(19) United States
(12) Patent Application Publication
(10) Pub. No.: US 2023/0142183 A1
(43) Pub. Date: May 11, 2023

(54) SEMICONDUCTOR DEVICE AND METHOD FOR FABRICATING THE SAME

(71) Applicant: SK hynix Inc., Icheon-si (KR)

(72) Inventors: Cha Deok DONG, Icheon-si (KR); Keo Rock CHOI, Icheon-si (KR); Guk Cheon KIM, Icheon-si (KR)

(21) Appl. No.: 17/891,026

(22) Filed: Aug. 18, 2022

(30) Foreign Application Priority Data
Nov. 5, 2021 (KR) 10-2021-0151117

(51) Int. Cl. H01L 27/22; H01L 43/12

(52) U.S. Cl. CPC H01L 27/224; H01L 43/12

(57) ABSTRACT

A method for fabricating a semiconductor device including a plurality of memory cells. The method includes: forming a first electrode layer; forming an initial Si-containing layer over the first electrode layer; performing a radical oxidation process to covert a first portion of the initial Si-containing layer into an oxide layer including silicon dioxide (SiO₂) and form a Si-containing layer under the oxide layer by using a second portion of the initial Si-containing layer; and incorporating a dopant into the oxide layer by an ion implantation process to form a selector pattern.

### PRIORITY CLAIM AND CROSS-REFERENCE TO RELATED APPLICATION

This patent document claims the priority under 35 U.S.C. § 119 to Korean Patent Application No. 10-2021-0151117 filed on Nov. 5, 2021, which is incorporated herein by reference in its entirety.

### TECHNICAL FIELD

The technology and implementations disclosed in this patent document relates to memory circuits or devices and their applications in electronic devices or systems.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices can store data by switching between different resistance states according to an applied voltage or current. The semiconductor devices may include an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device capable of improving operating characteristics of a semiconductor device and preventing process defects.

In one aspect, a semiconductor device including a plurality of memory cells, and each of the plurality of memory cells includes: a first electrode pattern; and a selector pattern disposed on the first electrode pattern. The selector pattern includes a silicon oxide having an incorporated dopant which exhibits a higher density than a density of a silicon oxide formed by a deposition process using source gases including Si and O₂.

In another aspect, a method for fabricating a semiconductor device including a plurality of memory cells. The method may include: forming a first electrode layer; forming an initial Si-containing layer over the first electrode layer; performing a radical oxidation process to covert a first portion of the initial Si-containing layer into an oxide layer including silicon dioxide (SiO₂) and form a Si-containing layer under the oxide layer by using a second portion of the initial Si-containing layer; and incorporating a dopant into the oxide layer by an ion implantation process to form a selector pattern.

In another aspect, a method for fabricating a semiconductor device including a plurality of memory cells, the method may include: forming a first electrode layer over a substrate; forming an initial buffer layer over the first electrode pattern; forming an initial Si-containing layer over the initial buffer layer; performing a radical oxidation process to form an oxide layer including SiO₂, the oxide layer converted from at least a portion of the initial Si-containing layer and any remaining portion of the initial Si-containing layer forming a Si-containing layer; and incorporating a dopant into the oxide layer by an ion implantation process to form a selector pattern.

In another aspect, a method for fabricating a semiconductor device including a plurality of memory cells, the method may include: forming an initial capping layer on the plurality of memory cell; and performing a radical oxidation process so that a first portion of the initial capping layer is converted into a second capping layer including an oxide and a second portion of the initial capping layer remains as a first capping layer under the second capping layer.

### BRIEF DESCRIPTION OF THE DRAWINGS

FIGS. 1A to 1C illustrate a semiconductor device based on some implementations of the disclosed technology.

FIG. 1D illustrates an example of a Magnetic Tunnel Junction (MTJ) structure included in a variable resistance pattern based on some implementations of the disclosed technology.

FIGS. 2 to 7 are cross-sectional views illustrating an example method for forming a selector pattern based on some implementations of the disclosed technology.

FIGS. 8A to 8F are cross-sectional views illustrating an example of a semiconductor device and a method for fabricating the same based on some implementations of the disclosed technology.

### DETAILED DESCRIPTION

Hereinafter, various embodiments of the disclosure will be described in detail with reference to the accompanying drawings.

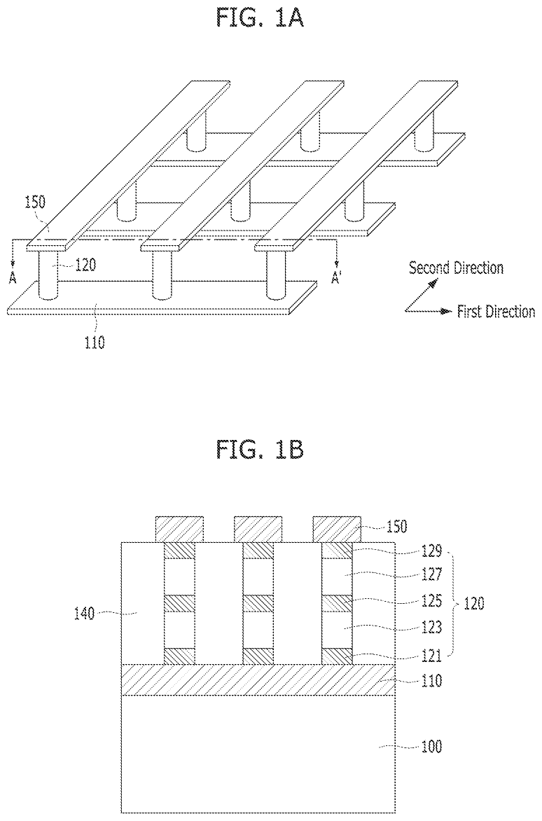

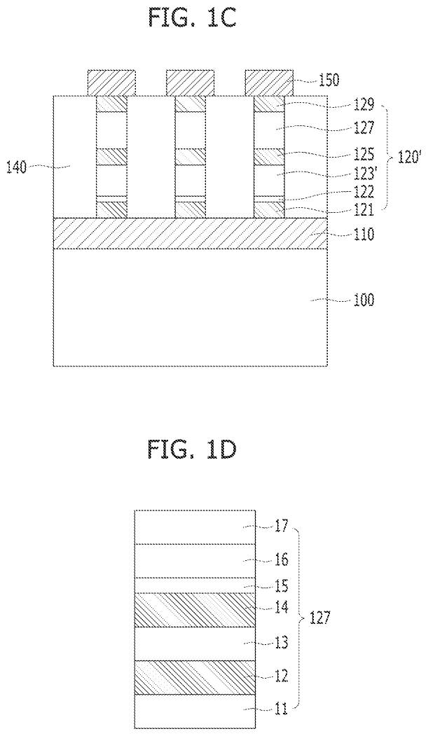

FIGS. 1A and 1B illustrate a semiconductor device based on some implementations of the disclosed technology. FIG. 1A is a perspective view, and FIG. 1B is a cross-sectional view taken along a line A-A′ of FIG. 1A.

Referring to FIGS. 1A and 1B, the semiconductor device may include a cross-point structure including a substrate 100, first lines 110 formed over the substrate 100 and extending in a first direction, second lines 150 formed over the first lines 110 to be spaced apart from the first lines 110 and extending in a second direction crossing the first direction, and memory cells 120 disposed at intersections of the first lines 110 and the second lines 150 between the first lines 110 and the second lines 150.

The substrate 100 may include a semiconductor material such as silicon. A required lower structure (not shown) may be formed in the substrate 100. For example, the substrate 100 may include a driving circuit (not shown) electrically connected to the first lines 110 and/or the second lines 150 to control operations of the memory cells 120.

The first line 110 and the second line 150 may be connected to a lower end and an upper end of the memory cell 120, respectively, and may transmit a voltage or a current to the memory cell 120 to drive the memory cell 120. When the first line 110 functions as a word line, the second line 150 may function as a bit line. Conversely, when the first line 110 functions as a bit line, the second line 150 may function as a word line. The first line 110 and the second line 150 may include a single-layer or multilayer structure including one or more of various conductive materials. Examples of the conductive materials may include a metal, a metal nitride, or a conductive carbon material, or a combination thereof, but are not limited thereto. For example, the first line 110 and the second line 150 may include tungsten (W), titanium (Ti), tantalum (Ta), platinum (Pt), aluminum (Al), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The memory cell 120 may be arranged in a matrix having rows and columns along the first direction and the second direction so as to overlap the intersection regions between the first lines 110 and the second lines 150. In an implementation, each of the memory cells 120 may have a size that is substantially equal to or smaller than that of the intersection region between each corresponding pair of the first lines 110 and the second lines 150. In another implementation, each of the memory cells 120 may have a size that is larger than that of the intersection region between each corresponding pair of the first lines 110 and the second lines 150.

Spaces between the first line 110, the second line 150 and the memory cell 120 may be filled with a dielectric material.

Referring to one specific example of the memory cell 120 illustrated in FIG. 1B, the memory cell 120 may include a stacked structure including a lower electrode pattern 121, a selector pattern 123 as a switching device to turn on or off the memory cell 120, a middle electrode pattern 125, a variable resistance pattern 127 for storing data in the memory cell 120 and an upper electrode pattern 129.

The lower electrode pattern 121 may be interposed between the first line 110 and the selector pattern 123 and disposed at a lowermost portion of each of the memory cells 120. The lower electrode pattern 121 may function as a circuit node that carries a voltage or a current between a corresponding one of the first lines 110 and the remaining portion (e.g., the elements 123, 125, 127 and 129) of each of the memory cells 120. The middle electrode pattern 125 may be interposed between the selector pattern 123 and the variable resistance pattern 127. The middle electrode pattern 125 may electrically connect the selector pattern 123 and the variable resistance pattern 127 to each other while physically separating the selector pattern 123 and the variable resistance pattern 127 from each other. The upper electrode pattern 129 may be disposed at an uppermost portion of the memory cell 120 and function as a transmission path of a voltage or a current between the rest of the memory cell 120 and a corresponding one of the second lines 150.

The lower electrode pattern 121, the middle electrode pattern 125 and the upper electrode pattern 129 may include a single-layer or multilayer structure including various conductive materials such as a metal, a metal nitride, or a conductive carbon material, or a combination thereof, respectively. For example, the lower electrode pattern 121, the middle electrode pattern 125 and the upper electrode pattern 129 may include tungsten (W), titanium (Ti), tantalum (Ta), platinum (Pt), aluminum (Al), copper (Cu), copper (Cu), zinc (Zn), nickel (Ni), cobalt (Co), lead (Pb), tungsten nitride (WN), tungsten silicide (WSi), titanium nitride (TiN), titanium silicon nitride (TiSiN), titanium aluminum nitride (TiAlN), tantalum nitride (TaN), tantalum silicon nitride (TaSiN), tantalum aluminum nitride (TaAlN), carbon (C), silicon carbide (SiC), or silicon carbon nitride (SiCN), or a combination thereof.

The lower electrode pattern 121, the middle electrode pattern 125 and the upper electrode pattern 129 may include the same material as each other or different materials from each other.

The lower electrode pattern 121, the middle electrode pattern 125 and the upper electrode pattern 129 may have the same thickness as each other or different thicknesses from each other.

The selector pattern 123 may be used to control access to the variable resistance pattern 127 by turning on or off an electrical conductive path through the selector pattern 123 and thus the memory cell 120. For example, the selector pattern 123 may turn on to be electrically conductive or turn off to be electrically non-conductive based on the voltage applied to the selector pattern 123. When a magnitude of the applied voltage is less than a predetermined threshold value, the selector pattern 123 may be turned off to be electrically non-conductive and a current flowing through the selector pattern 123 is blocked or substantially limited. When a magnitude of the applied voltage is equal to or greater than the predetermined threshold value, the selector pattern 123 may be turned on to be electrically conductive and a current flowing through the memory cell 120 to abruptly increases. The selector pattern 123 may include an MIT (Metal Insulator Transition) material such as NbO₂, TiO₂, VO₂, WO₂, or others, an MIEC (Mixed Ion-Electron Conducting) material such as ZrO₂(Y₂O₃), Bi₂O₃—BaO, (La₂O₃)ₓ(CeO₂)₁₋ₓ, or others, an OTS (Ovonic Threshold Switching) material including chalcogenide material such as Ge₂Sb₂Te₅, As₂Te₃, As₂, As₂Se₃, or others, or a tunneling insulating material such as silicon oxide, silicon nitride, a metal oxide, or others. A thickness of the tunneling insulating layer is sufficiently small to allow tunneling of electrons under a given voltage or a given current. The selector pattern 123 may include a single-layer or multilayer structure.

In one implementation, the selector pattern 123 may be configured to perform the threshold switching operation that refers to turning on or off the selector pattern 123 while an external voltage applied to the selector pattern 123. For example, the selector pattern 123 may turn on or off by increasing or decreasing an absolute value of the external voltage. When the absolute value of the external voltage applied to the selector pattern 123 increases and becomes greater than a first threshold voltage, the selector pattern 123 may be turned on to be electrically conductive to allow a current flow therethrough, Once the selector pattern 124 is turned on, the increase of the external voltage causes an operation current flowing therethrough to increase nonlinearly. When the absolute value of the external voltage applied to the selector pattern 123 decreases after the selector pattern 123 is turned on and becomes less than a second threshold voltage, the selector pattern 123 may be turned off to be electrically non-conductive. Once the selector pattern 123 is turned off, the decrease of the external voltage causes an operation current flowing therethrough to decrease nonlinearly. As such, the selector pattern 123 performing the threshold switching operation may have a non-memory operation characteristic.

In the material layer used for the selector pattern 123, there is provided a doped area which allows the selector pattern 123 to perform the threshold switching operation. The threshold switching operation of the selector pattern 123 may be controlled based on characteristics of the doped area, for example, a size of the doped area. Dopants incorporated into the selector pattern 123 can form a trap for conductive carries within the selector pattern 123. The threshold switching operation of the selector pattern 120 may be realized by capturing carriers or making carriers conductive while the carriers move between the middle electrode pattern 125 and the upper electrode pattern 129 in response to an application of an external voltage.

In some implementations, the selector pattern 123 may include a dielectric material having incorporated dopants. The selector pattern 123 may include an oxide with dopants, a nitride with dopants, or an oxynitride with dopants, or a combination thereof such as silicon oxide, titanium oxide, aluminum oxide, tungsten oxide, hafnium oxide, tantalum oxide, niobium oxide, silicon nitride, titanium nitride, aluminum nitride, tungsten nitride, hafnium nitride, tantalum nitride, niobium nitride, silicon oxynitride, titanium oxynitride, aluminum oxynitride, tungsten oxynitride, hafnium oxynitride, tantalum oxynitride, or niobium oxynitride, or a combination thereof. The dopants doped into the selector pattern 123 may include an n-type dopant or a p-type dopant and be incorporated for example, by ion implantation process. Examples of the dopants may include one or more of boron (B), nitrogen (N), carbon (C), phosphorous (P), arsenic (As), aluminum (Al), silicon (Si) or germanium (Ge).

In a comparative example, when the selector pattern 123 includes an oxide layer with a dopant, the selector pattern 123 may be formed by forming the oxide layer and incorporating the dopant into the oxide layer. The oxide layer may be formed by using a common deposition process such as a chemical vapor deposition (CVD) process, a physical vapor deposition (PVD) process, an atomic layer deposition (ALD), or others. For example, a SiO₂ layer may be formed by mixing source gases including Si and O₂ through the deposition processes as described above. The oxide layer formed by the deposition processes (referred to as a deposition-type oxide layer) has a relatively low density. The deposition-type oxide layer has a structure with a relatively large amount of vacancy or void. Therefore, when the dopant is introduced into the oxide layer in a subsequent process, undesirable micro voids may be formed in the selector pattern 123 and a portion of a surface of the lower electrode pattern 121 may be damaged due to the presence of the micro voids. As a result, an interface between the selector pattern 123 and the lower electrode pattern 121 may become unclear and the electrical connection at the interface may be compromised, thereby deteriorating a performance of the memory cell 120.

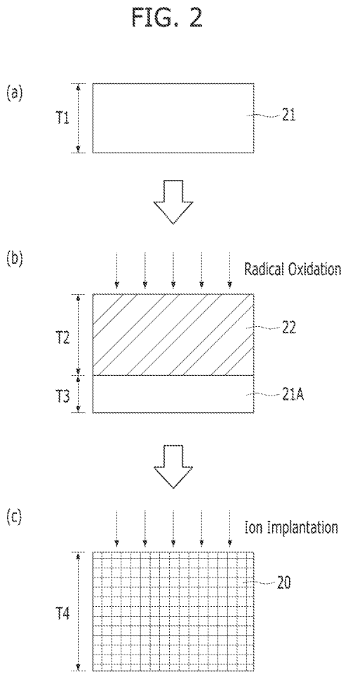

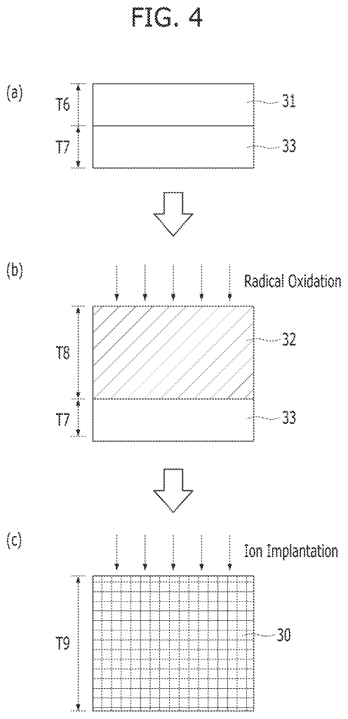

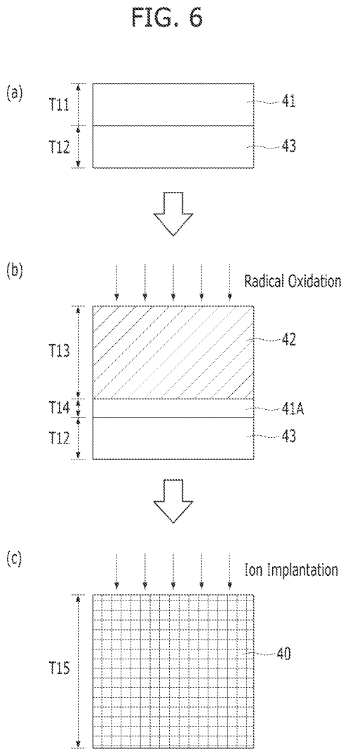

In recognition of the issues above in the implementation of the disclosed technology, selector patterns (see the reference numeral 20 of FIG. 2, the reference numeral 30 of FIG. 4 and the reference numeral 40 of FIG. 6) for forming the selector pattern 123 may be formed by forming a high-density oxide layer (see the reference numeral 22 of FIG. 2, the reference numeral 32 of FIG. 4, and the reference numeral 42 of FIG. 6) as compared to the deposition-type oxide layer and incorporating a dopant into the oxide layer. Each of the oxide layers 22, 32 and 42 has a relatively lower vacancy or void so as to exhibit a good TDDB (Time Dependent Dielectric Breakdown) characteristic. A dielectric layer having an excellent TDDB characteristic can be considered as a hard and durable dielectric layer. Each of the oxide layers 22, 32 and 42 having a high density may be formed by forming each of initial Si-containing layers (see the reference numeral 21 of FIG. 2, the reference numeral 31 of FIG. 4, and the reference numeral 41 of FIG. 6) and performing a radical oxidation process to the layers, instead of forming an oxide layer by using the deposition process such as CVD, PVD or ALD. In implementations, the oxide layers 22, 32 and 42 having a high density and a desired thickness may be formed by the radical oxidation process, while a portion of Si-containing layers (see the reference numeral 21A of FIG. 2, and the reference numeral 41A of FIG. 6) or a portion of initial buffer layers (see the reference numeral 33 of FIG. 4, and the reference numeral 43 of FIG. 6) may remain with a certain thickness. The portion of the Si-containing layers (see the reference numeral 21A of FIG. 2, and the reference numeral 41A of FIG. 6) or the portion of initial buffer layers (see the reference numeral 33 of FIG. 4, and the reference numeral 43 of FIG. 6) may be disposed under the oxide layers 22, 32 and 42. The high-density oxide layers 22, 32 and 42, and the remaining Si-containing layers 21A and 41A or the remaining initial buffer layers 33 and 43 may be used to prevent, or reduce the level of, the formation of micro voids in the selector pattern 123 and protect the electrode structure of the lower electrode pattern 121 during a subsequent ion implantation process performed under harsh conditions. This leads to an improved interface and electrical connection between the selector pattern 123 and the lower electrode pattern 121.

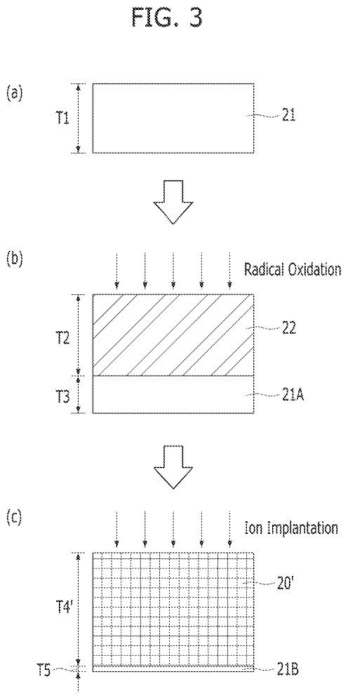

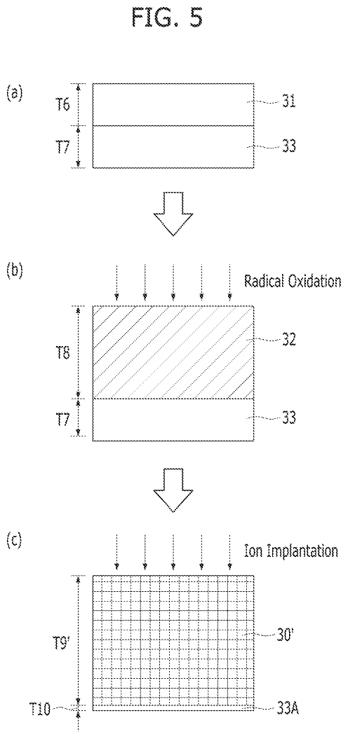

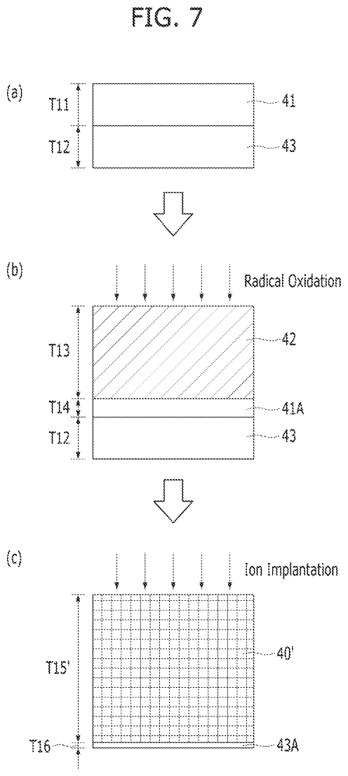

In some implantations, the remaining Si-containing layers 21A and 41A, or the remaining initial buffer layers 33 and 43 may be absorbed into the selector pattern 123 during the subsequent ion implantation process. Thus, after the ion implantation process, the Si-containing layers 21A and 41A, or the initial buffer layers 33 and 43 may not exist. In some implantations, after the ion implantation process, a portion of the remaining Si-containing layer 21A and a portion of the remaining initial buffer layers 33 and 43 may remain with a thickness that is sufficiently small not to affect an electrical characteristic of the memory cell 120 (see the reference numeral 21B of FIG. 3, the reference numeral 33A of FIG. 5 and the reference numeral 43A of FIG. 7).

The formation of the selector patterns 20, 30 and 40 for forming the selector pattern 123 will be described in detail with reference to FIGS. 2, 4 and 6.

The variable resistance pattern 127 may be used to store data using the different resistance states of the variable resistance pattern 123 (e.g., using high and low resistance states to represent digital level “1” and “0”) by setting the variable resistance pattern 123 into a desired resistance state, and to change a stored data bit by switching between different resistance states according to an applied voltage or current. The variable resistance pattern 127 may have a single-layered structure or a multi-layered structure including at least one of materials used for an RRAM, a PRAM, an MRAM, an FRAM, or others. For example, variable resistance pattern 127 may include a material used for the RRAM, the PRAM, the MRAM, the FRAM, or others, such as a material having a variable resistance characteristic used for the RRAM, the PRAM, the MRAM, the FRAM, or others. For example, the variable resistance pattern 127 may include a metal oxide such as a transition metal oxide or a perovskite-based oxide, a phase change material such as a chalcogenide-based material, a ferromagnetic material, a ferroelectric material, or others. However, the implementations are not limited thereto, and the memory cell 120 may include other memory layers capable of storing data in various ways without being limited to the variable resistance pattern 127.

In some implementations, the variable resistance pattern 127 may include a magnetic tunnel junction (MTJ) structure. This will be explained with reference to FIG. 1D.

FIG. 1D illustrates an example of a Magnetic Tunnel Junction (MTJ) structure included in the variable resistance pattern 127.

The variable resistance pattern 127 may include an MTJ structure including a free layer 12 having a variable magnetization direction, a pinned layer 14 having a pinned magnetization direction and a tunnel barrier layer 13 interposed between the free layer 12 and the pinned layer 14.

The free layer 12 may have one of different magnetization directions or one of different spin directions of electrons to switch the polarity of the free layer 12 in the MTJ structure, resulting in changes in resistance value. In some implementations, the polarity of the free layer 12 is changed or flipped upon application of a voltage or current signal (e.g., a driving current above a certain threshold) to the MTJ structure. With the polarity changes of the free layer 12, the free layer 12 and the pinned layer 14 have different magnetization directions or different spin directions of electron, which allows the variable resistance pattern 127 to store different data or represent different data bits. The free layer 12 may also be referred as a storage layer. The magnetization direction of the free layer 12 may be substantially perpendicular to a surface of the free layer 12, the tunnel barrier layer 13 and the pinned layer 14. Thus, the magnetization direction of the free layer 12 may be substantially parallel to stacking directions of the free layer 12, the tunnel barrier layer 13 and the pinned layer 14. Therefore, the magnetization direction of the free layer 12 may be changed between a downward direction and an upward direction. The change in the magnetization direction of the free layer 12 may be induced by a spin transfer torque generated by an applied current or voltage.

The free layer 12 may have a single-layer or multilayer structure including a ferromagnetic material. For example, the free layer 12 may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or others, or may include a stack of metals, such as Co/Pt, or Co/Pd, or others.

The tunnel barrier layer 13 may allow the tunneling of electrons in both data reading and data writing operations. In a write operation for storing new data, a high write current may be directed through the tunnel barrier layer 13 to change the magnetization direction of the free layer 12 and thus to change the resistance state of the MTJ for writing a new data bit. In a reading operation, a low reading current may be directed through the tunnel barrier layer 13 without changing the magnetization direction of the free layer 12 to measure the existing resistance state of the MTJ under the existing magnetization direction of the free layer 12 to read the stored data bit in the MTJ. The tunnel barrier layer 13 may include a dielectric oxide such as MgO, CaO, SrO, TiO, VO, or NbO or others.

The pinned layer 14 may have a pinned magnetization direction, which remains unchanged while the magnetization direction of the free layer 12 changes. The pinned layer 14 may be referred to as a reference layer. In some implementations, the magnetization direction of the pinned layer 14 may be pinned in a downward direction. In some implementations, the magnetization direction of the pinned layer 14 may be pinned in an upward direction.

The pinned layer 14 may have a single-layer or multilayer structure including a ferromagnetic material. For example, the pinned layer 14 may include an alloy based on Fe, Ni or Co, for example, an Fe—Pt alloy, an Fe—Pd alloy, a Co—Pd alloy, a Co—Pt alloy, a Co—Fe alloy, an Fe—Ni—Pt alloy, a Co—Fe—Pt alloy, a Co—Ni—Pt alloy, or a Co—Fe—B alloy, or may include a stack of metals, such as Co/Pt, or Co/Pd or others.

If a voltage or current is applied to the variable resistance pattern 127, the magnetization direction of the free layer 12 may be changed by spin torque transfer. In some implementations, when the magnetization directions of the free layer 12 and the pinned layer 14 are parallel to each other, the variable resistance pattern 127 may be in a low resistance state, and this may indicate digital data bit “0.” Conversely, when the magnetization directions of the free layer 12 and the pinned layer 14 are anti-parallel to each other, the variable resistance pattern 127 may be in a high resistance state, and this may indicate a digital data bit “1.” In some implementations, the variable resistance pattern 127 can be configured to store data bit ‘1’ when the magnetization directions of the free layer 12 and the pinned layer 14 are parallel to each other and to store data bit ‘0’ when the magnetization directions of the free layer 12 and the pinned layer 14 are anti-parallel to each other.

In some implementations, the variable resistance pattern 127 may further include one or more layers performing various functions to improve a characteristic of the MTJ structure. For example, the variable resistance pattern 127 may further include at least one of an under layer 11, a spacer layer 15, a magnetic correction layer 16, or a protection layer 17.

The under layer 11 may be disposed under the free layer 12 and serve to improve perpendicular magnetic crystalline anisotropy of the free layer 12. The under layer 11 may have a single-layer or multilayer structure including a metal, a metal alloy, a metal nitride, or a metal oxide, or a combination thereof. For example, the under layer 11 may include one or more of TaN, AlN, SiN, TiN, VN, CrN, GaN, GeN, ZrN, NbN, MoN or HfN.

The spacer layer 15 may be interposed between the pinned layer 14 and the magnetic correction layer 16 and function as a buffer between the magnetic correction layer 16 and the pinned layer 14. The spacer layer 15 may serve to improve characteristics of the magnetic correction layer 16. The spacer layer 15 may include a noble metal such as ruthenium (Ru).

The magnetic correction layer 16 may serve to offset the effect of the stray magnetic field produced by the pinned layer 14. In this case, the effect of the stray magnetic field of the pinned layer 14 can decrease, and thus a biased magnetic field in the free layer 12 can decrease. The magnetic correction layer 16 may have a magnetization direction anti-parallel to the magnetization direction of the pinned layer 14. In the implementation, when the pinned layer 14 has a downward magnetization direction, the magnetic correction layer 16 may have an upward magnetization direction. Conversely, when the pinned layer 14 has an upward magnetization direction, the magnetic correction layer 16 may have a downward magnetization direction. The magnetic correction layer 16 may be coupled with the pinned layer 14 via the spacer layer 15 to form a synthetic anti-ferromagnet (SAF) structure. The magnetic correction layer 16 may have a single-layer or multilayer structure including a ferromagnetic material.

In this implementation, the magnetic correction layer 16 is located above the pinned layer 14, but the magnetic correction layer 16 may disposed at a different location. For example, the magnetic correction layer 16 may be located above, below, or next to the MTJ structure while the magnetic correction layer 16 is patterned separately from the MTJ structure.

The protection layer 17 may be used to protect the variable resistance pattern 127. In some implementations, the protection layer 17 may include various conductive materials or an oxide. In some implementations, the protection layer 17 may include a metallic material having almost none or a small number of pin holes and high resistance to wet and/or dry etching. In some implementations, the protection layer 17 may include a metal, a nitride, or an oxide, or a combination thereof. For example, the protection layer 17 may include a noble metal such as ruthenium (Ru).

The protection layer 17 may have a single-layer or multilayer structure. In some implementations, the protection layer 17 may have a multilayer structure including an oxide, or a metal, or a combination thereof. For example, the protection layer 17 may have a multilayer structure of an oxide layer, a first metal layer and a second metal layer.

A material layer (not shown) for resolving the lattice structure differences and the lattice constant mismatch between the pinned layer 14 and the magnetic correction layer 16 may be interposed between the pinned layer 14 and the magnetic correction layer 16. For example, this material layer may be amorphous and may include a metal a metal nitride, or metal oxide.

In some implementations, each of the memory cell 120 may include the lower electrode pattern 121, the selector pattern 123, the middle electrode pattern 125, the variable resistance pattern 127 and the upper electrode pattern 129 which are sequentially stacked. In some implementations, the memory cells 120 may have different structures. For example, at least one of the lower electrode pattern 121, the middle electrode pattern 125 and the upper electrode pattern 129 may be omitted. In some implementations, the positions of the selector pattern 123 and the variable resistance pattern 127 may be reversed. In some implementations, in addition to the layers 121, 123, 125, 127 and 129 shown in FIG. 1B, the memory cells 120 may further include one or more layers (not shown) for enhancing characteristics of the memory cells 120 or improving fabricating processes.

In some implementations, neighboring memory cells of the plurality of memory cells 120 may be spaced apart from each other at a predetermined interval, and trenches may be present between the plurality of memory cells 120. A trench between neighboring memory cells 120 may have a height to width ratio (i.e., an aspect ratio) in a range from 1:1 to 40:1, from 10:1 to 40:1, from 10:1 to 20:1, from 5:1 to 10:1, from 10:1 to 15:1, from 1:1 to 25:1, from 1:1 to 30:1, from 1:1 to 35:1, or from 1:1 to 45:1.

In some implementations, the trench may have sidewalls that are substantially perpendicular to an upper surface of the substrate 100. In some implementations, neighboring trenches may be spaced apart from each other by an equal or similar distance.

In some implementations, the semiconductor device may include one or more additional layers in addition to the first line 110, the memory cell 120 and the second line 150. For example, a lower electrode contact may be further formed between the first line 110 and the lower electrode pattern 121 and an upper electrode contact may be further formed between the second line 150 and the upper electrode pattern 129.

Although one cross-point structure has been described as an example, two or more cross-point structures may be stacked in a vertical direction perpendicular to a top surface of the substrate 100.

In accordance with the implementations, the selector pattern 123 may be formed by depositing the initial Si-containing layers 21, 31 and 41, performing the radical oxidation process to form the high-density oxide layers 22, 32 and 42, and performing the ion implantation process to incorporate a dopant into the high-density oxide layers 22, 32 and 42. The high-density oxide layers 22, 32 and 42 refer to oxide layers having a higher density as compared to those formed by a deposition process. A portion of the Si-containing layers 21A and 41A or a portion of the initial buffer layers 33 and 43 may remain with a certain thickness after the radical oxidation process. Therefore, during the subsequent ion implantation process performed under harsh conditions, it is possible to prevent the formation of micro voids in the selector pattern 123 and protect the lower electrode pattern 121. Further, during the ion implantation process, since the remaining Si-containing layers 21A and 41A, or the remaining initial buffer layers 33 and 43 may be absorbed into the selector pattern 123, the resistance control of the memory cell 120 may be facilitated. The finally formed selector pattern 123 may include the high-density oxide layer with the dopant.

FIG. 1C illustrates a semiconductor device based on some implementations of the disclosed technology.

The semiconductor device illustrated in FIG. 1C may include a memory cell 120′. The memory cell 120′ may include a stacked structure including a lower electrode pattern 121, a buffer layer pattern 122, a selector pattern 123′, a middle electrode pattern 125, a variable resistance pattern 127 and an upper electrode pattern 129. The memory cell 120′ illustrated in FIG. 1C may be similar to the memory cell 120 illustrated in FIG. 1B except that the memory cell further includes the buffer layer pattern 122 interposed between the lower electrode pattern 121 and the selector pattern 123′. The implementations illustrated in FIG. 1C will be described focusing on differences from the implementations illustrated in FIG. 1B.

The buffer layer pattern 122 may be interposed between the lower electrode pattern 121 and the selector pattern 123′. The buffer layer pattern 122 may be formed by patterning a buffer layer (see the reference numeral 21B of FIG. 3), a buffer layer (see the reference numeral 33A of FIG. 5) and a buffer layer (see the reference numeral 43A of FIG. 7). The buffer layer pattern 122 may be formed with a Si-containing layer (see the reference numeral 21A of FIG. 3) and initial buffer layers (see the reference numeral 33 of FIG. 5 and the reference numeral 43 of FIG. 7), which remain with a certain thickness after an ion implantation process. In the implementation, although a portion of the Si-containing layer 21A and a portion of the initial buffer layers 33 and 43 remain after the ion implantation process to form the buffer layer 21B, the buffer layer 33A and the buffer layer 43A, respectively, it is possible to control thicknesses of the buffer layer 21B, the buffer layer 33A and the buffer layer 43A to a level that does not affect an electrical characteristic of the memory cell 120. Accordingly, it may be easy to control a resistance of the memory cell 120′ as needed.

As a result, the buffer layer pattern 122 may have a thin thickness that does not affect an electrical characteristic of the memory cell 120 when a current flows. Thus, a thickness of the buffer layer pattern 122 is sufficiently small without having electrical significance. For example, the buffer layer pattern 122 may have a thickness in a range of greater than 0 Å and less than or equal to 10 Å.

The buffer layer pattern 122 may include a material derived from an initial Si-containing layer (see the reference numeral 21 of FIG. 3) or a material derived from initial buffer layers (see the reference numeral 33 of FIG. 5, or the reference numeral 43 of FIG. 7).

In some implementations, the buffer layer pattern 122 may include a metal-free amorphous material. In some implementations, the buffer layer pattern 122 may include a Si-containing material, or a carbon material, or a combination thereof. In some implementations, the buffer layer pattern 122 may include Si₃N₄, SiOₓN_{y}, WSiₓ, CoSiₓ, SiOC, SiC, SiCN, amorphous Si, poly-Si, or carbon, or a combination thereof. In some implementations, the buffer layer pattern 122 may include a Si-containing material, or a carbon material, or a combination thereof, which does not contain a metal. In some implementations, the buffer layer pattern 122 may include Si₃N₄, SiOₓN_{y}, SiOC, SiC, SiCN, amorphous Si, poly-Si, or carbon, or a combination thereof. In some implementations, the buffer layer pattern 122 may include a stacked structure having a carbon-containing layer and a Si₃N₄-containing layer.

The formation of the buffer layers 21B, 33A and 43A for forming the buffer layer pattern 122 will be described in detail with reference to FIGS. 3, 5 and 7.

Next, an example of a method for fabricating the semiconductor device will be described with reference to FIGS. 1A to 1C.

Referring to FIGS. 1A to 1C, first lines 110 may be formed over a substrate 100 in which a predetermined structure is formed. The first lines 110 may be formed by forming a conductive layer for forming the first lines 110 and etching the conductive layer using a mask pattern in a line shape extending in a first direction. A material layer for forming a lower electrode pattern 121 may be formed over the first lines 110. Then, one of selector patterns 20, 20′, 30, 30′, 40 and 40′ may be formed over the material layer for forming the lower electrode pattern 121. The formation of the selector patterns 20, 30 and 40 for forming a selector pattern 123 will be described with reference to FIGS. 2, 4 and 6, and the formation of the selector patterns 20′, 30′ and 40′ for forming a selection pattern 123′ will be described with reference to FIGS. 3, 5 and 7.

FIGS. 2 to 7 are cross-sectional views illustrating an example method for forming a selector pattern based on some implementations of the disclosed technology.

Referring to FIG. 2, in step (a), an initial Si-containing layer 21 may be formed over a structure (not shown), for example, over the material layer for forming the lower electrode pattern 121.

The initial Si-containing layer 21 may function as a Si source of silicon oxide included in the selector pattern 123. A portion of the initial Si-containing layer 21 may remain as a Si-containing layer 21A after a radical oxidation process in step (b). The initial Si-containing layer 21 may include a Si-containing material. The Si-containing material may be selected in consideration of a desired resistance and a switching characteristic.

In some implementations, the initial Si-containing layer 21 may include Si₃N₄, SiOₓN_{y}, WSiₓ, CoSiₓ, SiOC, SiC, SiCN, amorphous Si, or poly-Si, or a combination thereof. In some implementations, the initial Si-containing layer 21 may include a Si-containing material which does not contain a metal. In some implementations, the initial Si-containing layer 21 may include Si₃N₄, SiOxNy, SiOC, SiC, SiCN, amorphous Si, or poly-Si, or a combination thereof.

The initial Si-containing layer 21 may be formed by a deposition process such a PVD process.

A thickness T1 of the initial Si-containing layer 21 may be determined in consideration of a thickness T2 of an oxide layer 22 and a thickness T3 of the remaining Si-containing layer 21A in step (b).

In step (b), the radical oxidation process may be performed on a portion having a predetermined depth from an upper surface of the initial Si-containing layer 21. Through the radical oxidation process, an oxide layer 22 including SiO₂ may be formed. At the same time, a portion of the initial Si-containing layer 21 may not be oxidized and remain under the oxide layer 22. The remaining initial Si-containing layer 21 may be referred to as the Si-containing layer 21A.

According to the radical oxidation process, radicals such as H*, O*, OH*, or others may be formed from Hz, 02, or others under a low-pressure high-temperature atmosphere or under a low-pressure plasma state. Therefore, it is possible to maximize a reactivity with Si and enable a rapid oxidation of the initial Si-containing layer 21, thereby forming the oxide layer 22 including a high-density SiO₂. At this time, by controlling a degree of oxidation, e.g., a thickness of the oxide layer 22 and a thickness of the Si-containing layer 21A, it is possible to protect the material layer for forming the lower electrode pattern 121 during a subsequent ion implantation process.

In some implementations, the radical oxidation process may be performed by using H₂ and O₂ gases under a high-temperature and a low-pressure atmosphere. In the high-temperature and the low-pressure atmosphere, the temperature may be about 700° C. or higher, and the pressure may be at a level corresponding to a high-vacuum, for example, in a range of about 10 Torr to 0.1 Torr. For example, an upper limit of the temperature may be determined depending on specific process conditions based on the common knowledge of the skilled person. When the radical oxidation process is performed outside the above conditions, radicals such as H*, O*, OH*, or others may not be properly formed, and thus the oxide layer 22 may not be properly formed.

In some implementations, the radical oxidation process may be performed by using a low-temperature plasma process. The low-temperature plasma process may be performed by using H₂ and O₂ gases under a pressure of about 10 mTorr to 10 Torr, a temperature of about 100° C. to 500° C., and radio frequency power of about 100 W to 5 kW. When the radical oxidation process is performed outside the above conditions, radicals such as H*, O*, OH*, or others may not be properly formed, and thus the oxide layer 22 may not be properly formed.

The oxide layer 22 formed by the radical oxidation process may have a relatively high density as compared to the deposition-type oxide layer formed by mixing source gases including Si and O₂ through a deposition process such as PVD, CVD, or ALD.

A thickness T2 of the oxide layer 22 may be greater than a value obtained by subtracting a thickness T3 of the Si-containing layer 21A from a thickness T1 of the initial Si-containing layer 21. Thus, the amount of the initial Si-containing layer 21 used for forming the oxide layer 22 may be expressed as T1-T3 in terms of a thickness. The thickness T2 of the oxide layer 22 may be greater than the thickness T1-T3 corresponding to the used amount of the initial Si-containing layer 21 for forming the oxide layer 22.

At this time, the amount of the initial Si-containing layer 21 used for forming the oxide layer 22 may vary depending on a material and a process for forming the initial Si-containing layer 21. An amount of Si required to form a SiO₂ layer having a predetermined thickness may be specified. The Si content in the Si-containing layer 21 may vary depending on the material for forming the initial Si-containing layer 21. Even if the same material is used, the Si content in the initial Si-containing layer 21 may vary depending on the process for forming the initial Si-containing layer 21. The amount (which may be expressed as a thickness) of the initial Si-containing layer 21 used for forming the oxide layer 22 may be experimentally calculated. Therefore, the thickness T1 of the initial Si-containing layer 21 may be determined in consideration of the calculated thickness of the initial Si-containing layer 21 and the thickness T3 of the Si-containing layer 21A.

Then, in step (c), a selector pattern 20 may be formed by incorporating a dopant into the oxide layer 22 through an ion implantation process.

The selector pattern 20 may include SiO₂ with a dopant. The dopant incorporated by the ion implantation process may include one or more boron (B), nitrogen (N), carbon (C), phosphorous (P), arsenic (As), aluminum (Al), or germanium (Ge).

The ion implantation process is performed with a high energy and a high dose and ions such as arsenic (As) ions are heavy component having a high mass. Therefore, the ion implantation process is performed under harsh conditions, in which a layer is difficult to withstand. However, in the implementations, since the oxide layer 22 formed by the radical oxidation process has a relatively high density, the oxide layer 22 may withstand the harsh conditions of the ion implantation process, thereby preventing the formation of defects such as micro voids. Moreover, the Si-containing layer 21A remaining under the oxide layer 22 may function as a buffer to minimize damage to the lower electrode pattern 121. The Si-containing layer 21A may be entirely removed during the ion implantation process and absorbed in the selector pattern 20. Thus, the Si-containing layer 21A may not exist after the ion implantation process.

A thickness T4 of the selector pattern 20 may be equal to the sum of the thickness T2 of the oxide layer 22 and the thickness T3 of the Si-containing layer 21A.

The selector pattern 20 may correspond to a selector pattern for forming the selector pattern 123 illustrated in FIG. 1B.

A method for forming a selector pattern 20′ illustrated in FIG. 3 may be similar to the method for forming the selector pattern 20 illustrated in FIG. 2, except that a portion of a Si-containing layer 21A is not absorbed into the selector pattern 20′ and remains during an ion implantation process. The implementation illustrated in FIG. 3 will be described focusing on differences from the implementation illustrated in FIG. 2.

Referring to FIG. 3, in step (a), an initial Si-containing layer 21 may be formed over a structure (not shown), for example, over the material layer for forming the lower electrode pattern 121.

In step (b), a radical oxidation process may be performed to form an oxide layer 22 including SiO₂. A portion of the initial Si-containing layer 21 may not be oxidized and remain as the Si-containing layer 21A under the oxide layer 22.

In step (c), the selector pattern 20′ may be formed by incorporating a dopant into the oxide layer 22 through an ion implantation process. At this time, one portion of the Si-containing layer 21A may be removed and absorbed into the selector pattern 20′ and the other portion of the Si-containing layer 21A may remain under the selector pattern 20′. The remaining portion of the Si-containing layer 21A may be referred to as a buffer layer 21B.

The buffer layer 21B may have a thickness that is sufficiently thin not to affect an electrical characteristic of the memory cell 120′. Thus, a thickness of the buffer layer 21B has no electrical significance. In some implementations, a thickness T5 of the buffer layer 21B may be in a range of greater than 0 Å and less than or equal to 10 Å.

The selector pattern 20′ may include SiO₂ with a dopant. A thickness T4′ of the selector pattern 20′ may be smaller than the thickness T4 of the selector pattern 20 illustrated in FIG. 2. The sum of the thickness T4′ of the selector pattern 20′ and the thickness T5 of the buffer layer 21B may be equal to the sum of the thickness T2 of the oxide layer 22 and the thickness T3 of the Si-containing layer 21A.

The selector pattern 20′ may correspond to a selector pattern for forming the selector pattern 123′ illustrated in FIG. 1C, and the buffer layer 21B may correspond to a buffer layer for forming the buffer layer pattern 122 illustrated in FIG. 1C.

A method for forming a selector pattern 30 illustrated in FIG. 4 may be similar to the method for forming the selector pattern 20 illustrated in FIG. 2 except that an initial buffer layer 33 is further formed under an initial Si-containing layer 31, and the initial Si-containing layer 31 is entirely oxidized by a radical oxidation process and does not remain after the radical oxidation process. The implementation illustrated in FIG. 4 will be described focusing on the difference from the implementation illustrated in FIG. 2.

Referring to FIG. 4, in step (a), the initial buffer layer 33 and the initial Si-containing layer 31 may be sequentially formed over a structure (not shown), for example, over the material layer for forming the lower electrode pattern 121.

The initial buffer layer 33 may be used to protect the lower electrode pattern 121 during a subsequent ion implantation process in step (c) and prevent damage to the lower electrode pattern 121. In some implementations, the initial buffer layer 33 may include a metal-free amorphous material. In some implementations, the initial buffer layer 33 may include Si₃N₄, or carbon, or a combination thereof. In some implementations, the initial buffer layer 33 may include a stacked structure of a carbon-containing layer and a Si₃N₄-containing layer.

A thickness T6 of the initial Si-containing layer 31 may be determined in consideration of a thickness T8 of an oxide layer 32.

In step (b), a radical oxidation process may be performed to convert the entire initial Si-containing layer 31 into an oxide layer 32 including SiO₂. The initial buffer layer 33 may entirely remain under the oxide layer 32.

All the initial Si-containing layer 31 may be used for forming the oxide layer 32. Thus, after the radical oxidation process, the initial Si-containing layer 31 may not exist.

The thickness T8 of the oxide layer 32 may be greater than the thickness T6 of the initial Si-containing layer 31.

In step (c), the selector pattern 30 may be formed by incorporating a dopant into the oxide layer 32 through an ion implantation process. At this time, since the initial buffer layer 33 may function as a buffer during the ion implantation process, damage to the lower electrode pattern 121 may be minimized. The initial buffer layer 33 may be removed and absorbed into the selector pattern 30 during the ion implantation process. Thus, after the ion implantation process, the initial buffer layer 33 may not exist.

The selector pattern 30 may include SiO₂ with a dopant. A thickness T9 of the selector pattern 30 may be equal to the sum of the thickness T8 of the oxide layer 32 and a thickness T7 of the initial buffer layer 33.

The selector pattern 30 may correspond to a selector pattern for forming the selector pattern 123 illustrated in FIG. 1B.

A method for forming a selector pattern 30′ illustrated in FIG. 5 may be similar to the method for forming the selector pattern 30 illustrated in FIG. 4 except that a portion of an initial buffer layer 33 may not be absorbed into the selector pattern 30′ and remain during an ion implantation process. The implementation illustrated in FIG. 5 will be described focusing on differences from the implementation illustrated in FIG. 4.

Referring to FIG. 5, in step (a), an initial buffer layer 33 and an initial Si-containing layer 31 may be sequentially formed over a structure (not shown), for example, over the material layer for forming the lower electrode pattern 121.

In step (b), a radical oxidation process may be performed to convert the entire initial Si-containing layer 31 into an oxide layer 32 including SiO₂. The initial buffer layer 33 may entirely remain under the oxide layer 32.

In step (c), the selector pattern 30′ may be formed by incorporating a dopant into the oxide layer 32 through an ion implantation process. At this time, one portion of the initial buffer layer 33 may be removed and absorbed into the selector pattern 30′, and the other portion of the initial buffer layer 33 may remain under the selector pattern 30′. The remaining portion of the initial buffer layer 33 may be referred to as a buffer layer 33A.

The buffer layer 33A may have a thickness that is sufficiently thin enough not to affect an electrical characteristic of the memory cell 120′. Thus, a thickness of the buffer layer 33A has no electrical significance. In some implementations, a thickness T10 of the buffer layer 33A may be in a range of greater than 0 Å and less than or equal to 10 Å.

The selector pattern 30′ may include SiO₂ with a dopant. A thickness T9′ of the selector pattern 30′ may be smaller than the thickness T9 of the selector pattern 30 illustrated in FIG. 4. The sum of the thickness T9′ of the selector pattern 30′ and the thickness T10 of the buffer layer 33A may be equal to the sum of a thickness T8 of the layer 32 and a thickness T7 of the initial buffer layer 33.

The selector pattern 30′ may correspond to a selector pattern for forming the selector pattern 123′ illustrated in FIG. 1C, and the buffer layer 33A may correspond to a buffer layer for forming the buffer layer pattern 122 illustrated in FIG. 1C.

A method for forming a selector pattern 40 illustrated in FIG. 6 may be similar to the method for forming the selector pattern 20 illustrated in FIG. 2 except that an initial buffer layer 43 may further formed under an initial Si-containing layer 41. The implementation illustrated in FIG. 6 will be described focusing on differences from the implementation illustrated in FIG. 2.

Referring to FIG. 6, in step (a), the initial buffer layer 43 and the initial Si-containing layer 41 may be sequentially formed over a structure (not shown), for example, over the material layer for forming the lower electrode pattern 121.

The initial buffer layer 43 may be used to protect the lower electrode pattern 121 during a subsequent ion implantation process in step (c) and prevent damage to the lower electrode pattern 121. In some implementations, the initial buffer layer 43 may include a metal-free amorphous material. In some implementations, the initial buffer layer 43 may include Si₃N₄, or carbon, or a combination thereof. In some implementations, the initial buffer layer 43 may include a stacked structure of a carbon-containing layer and a Si₃N₄-containing layer.

A thickness T11 of the initial Si-containing layer 41 may be determined in consideration of a thickness T13 of an oxide layer 42 and a thickness T14 of a Si-containing layer 41A.

In step (b), a radical oxidation process may be performed to convert one portion of the initial Si-containing layer 41 into the oxide layer 42 including SiO₂. At this time, the other portion of the initial Si-containing layer 41 may not be oxidized and remain. The remaining portion of the initial Si-containing layer 41 may be referred to as a Si-containing layer 41A. The initial buffer layer 43 may entirely remain under the Si-containing layer 41A.

The thickness T13 of an oxide layer 42 may be greater than the thickness T11 of the initial Si-containing layer 41.

In step (c), the selector pattern 40 may be formed by incorporating a dopant into the oxide layer 42 through an ion implantation process. At this time, since the Si-containing layer 41A and the initial buffer layer 43 may function as a buffer during the ion implantation process, damage to the lower electrode pattern 121 may be minimized. The Si-containing layer 41A and the initial buffer layer 43 may be entirely removed and absorbed into the selector pattern 40 during the ion implantation process. Thus, after the ion implantation process, the Si-containing layer 41A and the initial buffer layer 43 may not exist.

The selector pattern 40 may include SiO₂ with a dopant. A thickness T15 of the selector pattern 40 may be equal to the sum of the thickness T13 of the oxide layer 42, the thickness T14 of the Si-containing layer 41A and the thickness T12 of the initial buffer layer 43.

The selector pattern 40 may correspond to a selector pattern for forming the selector pattern 123 illustrated in FIG. 1B.

A method for forming a selector pattern 40′ illustrated in FIG. 7 may be similar to the method for forming the selector pattern 40 illustrated in FIG. 6 except that a portion of an initial buffer layer 43 is not absorbed into the selector pattern 40′ and remains during the ion implantation process. The implementation illustrated in FIG. 7 will be described focusing on differences from the implementation illustrated in FIG. 6.

Referring to FIG. 7, in step (a), the initial buffer layer 43 and the initial Si-containing layer 41 may be sequentially formed over a structure (not shown), for example, over the material layer for forming the lower electrode pattern 121.

In step (b), a radical oxidation process may be performed to convert one portion of the initial Si-containing layer 41 into the oxide layer 42 including SiO₂. At this time, the other portion of the initial Si-containing layer 41 may not be oxidized and remain under the oxide layer 42. The remaining portion of the initial Si-containing layer 41 may be referred to as a Si-containing layer 41A. The initial buffer layer 43 may entirely remain under the Si-containing layer 41A.

The thickness T13 of an oxide layer 42 may be greater than the thickness T11 of the initial Si-containing layer 41.

In step (c), the selector pattern 40 may be formed by incorporating a dopant into the oxide layer 42 through an ion implantation process. At this time, since the Si-containing layer 41A and the initial buffer layer 43 may function as a buffer during the ion implantation process, damage to the lower electrode pattern 121 may be minimized. The Si-containing layer 41A may be entirely removed and absorbed into the selector pattern 40′ during the ion implantation process. One portion of the initial buffer layer 43 may be removed and absorbed into the selector pattern 40′ during the ion implantation process, while the other portion of the initial buffer layer 43 may remain under the selector pattern 40′ during the ion implantation process. The remaining portion of the initial buffer layer 43 may be referred to as a buffer layer 43A.

The buffer layer 43A may have a thickness that is sufficiently thin enough not to affect an electrical characteristic of the memory cell 120′. Thus, a thickness of the buffer layer 43A has no electrical significance. In some implementations, a thickness T16 of the buffer layer 43A may be in a range of greater than 0 Å and less than or equal to 10 Å.

The selector pattern 40′ may include SiO₂ with a dopant. A thickness T15′ of the selector pattern 40′ may be smaller than the thickness T15 of the selector pattern 40. The sum of the thickness T15′ of the selector pattern 40′ and the thickness T16 of the buffer layer 43A may be equal to the sum of the thickness T13 of the oxide layer 42, the thickness T14 of the Si-containing layer 41A and the thickness T12 of the initial buffer layer 43.

The selector pattern 40 may correspond to a selector pattern for forming the selector pattern 123 illustrated in FIG. 1B.

The selector pattern 40′ may correspond to a selector pattern for forming the selector pattern 123′ illustrated in FIG. 1C, and the buffer layer 43A may correspond to a buffer layer for forming the buffer layer pattern 122 illustrated in FIG. 1C.

In the implementation illustrated in FIG. 7, the Si-containing layer 41A does not remain after the ion implantation process. In some implementations, a portion of the Si-containing layer 41A may remain over the buffer layer 43A during the ion implantation process. In some implementations, the Si-containing layer 41A and the buffer layer 43A may remain under the selector pattern 40′.

Referring back to FIGS. 1A to 1C, the memory cell 120 or 120′ may be formed by sequentially forming material layers for forming the remaining portion (e.g., elements 125, 127 and 129) of the memory cell 120 or 120′ over the selector pattern for forming the selector pattern 123 or 123′, and etching the material layers for forming the remaining portion (e.g., elements 125, 127 and 129), the selector pattern for forming the selector pattern 123 and the material layer for forming the lower electrode pattern 121 by using a mask pattern. Then, second lines 150 may be formed by forming a conductive layer for forming the second lines 150 on the memory cell 120 or 120′ and etching the conductive layer using a mask pattern in a line shape extending in a second direction. Spaces between the first lines 110, the memory cells 120 and the second lines 150 may be filled with a dielectric material.

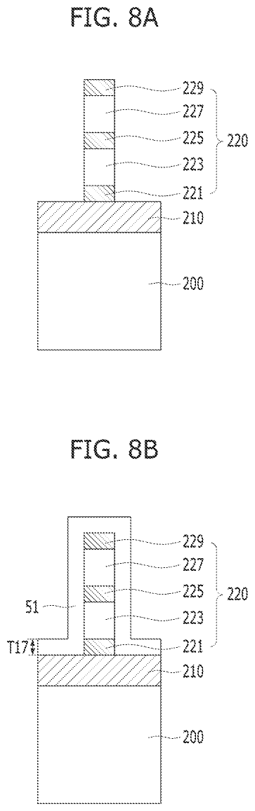

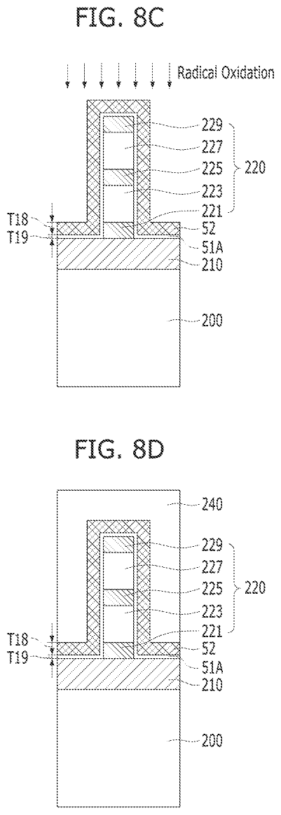

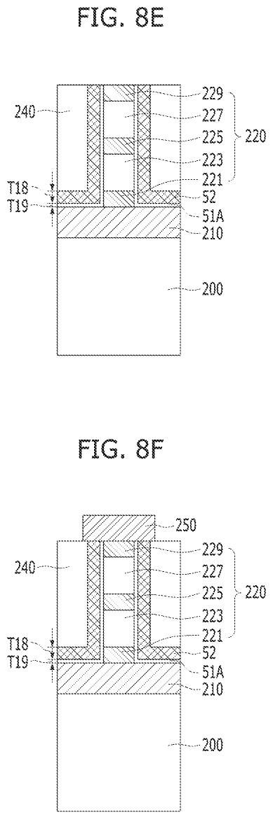

FIGS. 8A to 8F are cross-sectional views illustrating an example of a semiconductor device and a method for fabricating the same based on some implementations of the disclosed technology.

Referring to FIG. 8A, first lines 210 may be formed over a substrate 200 in which a predetermined structure is formed. The first lines 110 may be formed by forming a conductive layer for forming the first lines 110 and etching the conductive layer using a mask pattern in a line shape extending in a first direction.

A memory cell 220 may be formed by forming material layers for forming the memory cell 220 and etching the material layers using a mask pattern. The memory cell 220 may include a lower electrode pattern 221, a selector pattern 223, a middle electrode pattern 225, a variable resistance pattern 227 and an upper electrode pattern 229.

Referring to FIG. 8B, an initial capping layer 51 may be conformally formed on the structure of FIG. 8A.

The initial capping layer 51 may include a Si-containing material. For example, the initial capping layer 51 may include Si₃N₄, SiOₓN_{y}, WSiₓ, CoSiₓ, SiOC, SiC, SiCN, amorphous Si, or poly-Si, or a combination thereof.

A thickness T17 of the initial capping layer 51 may be determined in consideration of a thickness T18 of a second capping layer (see the reference numeral 52 of FIG. 8C) and a thickness T19 of a first capping layer (see the reference numeral 51A of FIG. 8C).

Referring to FIG. 8C, a radical oxidation process may be performed to convert one portion of the initial capping layer 51 into the second capping layer 52 including SiO₂. At this time, the other portion of the initial capping layer 51 may not be oxidized and remain. The remaining portion of the initial capping layer 51 may be referred to as the first capping layer 51A. The first capping layer 51A may be disposed to cover the memory cell 220 and an exposed surface of the first lines 210. The second capping layer 52 may be disposed to cover the first capping layer 51A. The details of the radical oxidation process may be similar to those described with reference to FIGS. 1A to 7.

In accordance with the implementations, a double-layer structure including the first capping layer 51A containing Si and the second capping layer 52 containing a high-density SiO₂. The double-layer structure may relieve stress on the memory cell 220, minimize intrusion of various elements that may affect the memory cell 220, and protect the memory cell 220.

In some implements, the second capping layer 52 may include SiO₂, and the first capping layer 51A may include Si₃N₄.

A thickness T18 of the second capping layer 52 may be greater than a thickness T17 of the initial capping layer 51.

In some implementations, a thickness T19 of the first capping layer 51A may be greater than 0 and less than or equal to 20% of the thickness T18 of the second capping layer 52.

Referring to FIG. 8D, an interlayer dielectric layer 240 may be formed on the structure of FIG. 8C. The interlayer dielectric layer 240 may be formed so as to fill spaces between the memory cells 220 and cover a top of the memory cells 220. The interlayer dielectric layer 240 may have a single-layer or multilayer structure including various dielectric materials such as silicon oxide, or silicon nitride, or a combination thereof.

Referring to FIG. 8E, a planarization process such as a chemical mechanical polishing (CMP) process may be performed until a top surface of the memory cell 220 is exposed.

Referring to FIG. 8F, second lines 250 may be formed by forming a conductive layer for the second lines 250 over the memory cell 220 and etching the conductive layer by using a mask pattern in a line shape extending in a second direction. Spaces between the second lines 250 may be filled with a dielectric material.

The semiconductor device may include the first lines 210, the memory cell 220 and the second lines 250. The memory cell 220 may include the lower electrode pattern 221, the selector pattern 223, the middle electrode pattern 225, the variable resistance pattern 227 and the upper electrode pattern 229 which are sequentially stacked. The semiconductor device may further include the first capping layer 51A and the second capping layer 52. The first capping layer 51A may be formed on the sidewalls of the memory cell 220 and on the exposed top surface of the first lines 210, and the second capping layer 52 may be formed on the first capping layer 51A. The double-layer structure including the first capping layer 51A containing Si and the second capping layer 52 containing a high-density SiO₂ may relieve stress on the memory cell 220, minimize intrusion of various elements that affect the memory cell 220 and protect the memory cell 220.

In the implementation, a portion of the initial capping layer 51 may remain as the first capping layer 51A after the radical oxidation process. In some implementations, the initial capping layer 51 may be entirely oxidized and not remain during the radical oxidation process. Even if the fist capping layer 51A does not exist, the second capping layer 52 having a relatively high density may exhibit a sufficient protection effect for the memory cell 220.

semiconductor device semiconductor device While this patent document contains many specifics, these should not be construed as limitations on the scope of any disclosure or of what may be claimed, but rather as descriptions of features that may be specific to particular embodiments of particular disclosures. Certain features that are described in this patent document in the context of separate embodiments may be implemented in combination in a single embodiment. Conversely, some of the features that are described in the context of a single embodiment may also be implemented in multiple embodiments separately or in certain suitable sub combinations. Moreover, although features may be described above in certain combinations, one or more features from a combination may in some cases be excised from the combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few embodiments and examples are described. Various enhancements and variations of the disclosed embodiments and other embodiments can be made based on what is described and illustrated in this patent document.

What is claimed is:

1. A method for fabricating a semiconductor device including a plurality of memory cells, the method comprising:
forming a first electrode layer;
forming an initial Si-containing layer over the first electrode layer;
performing a radical oxidation process to convert a first portion of the initial Si-containing layer into an oxide layer including silicon dioxide (SiO₂) and form a Si containing layer under the oxide layer by using a second portion of the initial Si-containing layer; and
incorporating a dopant into the oxide layer by an ion implantation process to form a selector pattern.

2. The method according to claim 1, wherein a thickness of the initial Si-containing layer is determined in consideration of a thickness of the oxide layer and a thickness of the Si-containing layer.

3. The method according to claim 1, wherein the initial Si-containing layer includes Si₃N₄, SiOₓN_{y}, WSiₓ, CoSiₓ, SiOC, SiC, SiCN, amorphous Si, or poly-Si, or a combination thereof.

4. The method according to claim 1, wherein the radical oxidation process is performed by a low-temperature plasma process under a pressure of 10 mTorr to 10 Torr, a temperature of 100° C. to 500° C., and radio frequency power of 100 W to 5 kW, or by using H₂ and O₂ gases under a temperature of 700° C. or higher and a pressure of 10 Torr to 0.1 Torr.

5. The method according to claim 1, wherein a thickness of the oxide layer is greater than a value obtained by subtracting a thickness of the Si-containing layer from a thickness of the initial Si-containing layer.

6. The method according to claim 1, wherein the dopant includes one or more boron (B), nitrogen (N), carbon (C), phosphorous (P), arsenic (As), aluminum (Al), or germanium (Ge).

7. The method according to claim 1, wherein the Si-containing layer is entirely removed and absorbed into the selector pattern during the ion implantation process.

8. The method according to claim 1, wherein, during the ion implantation process, a portion of the Si-containing layer is removed and absorbed into the selector pattern, and the other portion of the Si-containing layer remains as a buffer layer pattern under the election element layer.

9. The method according to claim 8, wherein the buffer layer has a thickness in a range of greater than 0 Å and less than or equal to 10 Å.

10. A method for fabricating a semiconductor device including a plurality of memory cells, the method comprising:
forming a first electrode layer over a substrate;
forming an initial buffer layer over the first electrode pattern;
forming an initial Si-containing layer over the initial buffer layer;
performing a radical oxidation process to form an oxide layer including SiO₂, the oxide layer converted from at least a portion of the initial Si-containing layer and any remaining portion of the initial Si-containing layer forming a Si-containing layer; and
incorporating a dopant into the oxide layer by an ion implantation process to form a selector pattern.

11. The method according to claim 10, wherein the initial Si-containing layer includes Si₃N₄, SiOₓN_{y}, WSiₓ, CoSiₓ, SiOC, SiC, SiCN, amorphous Si, or poly-Si, or a combination thereof.

12. The method according to claim 10, wherein the radical oxidation process is performed by a low-temperature plasma process under a pressure of 10 mTorr to 10 Torr, a temperature of 100° C. to 500° C., and radio frequency power of 100 W to 5 kW, or by using H₂ and O₂ gases under a temperature of 700° C. or higher and a pressure of 10 Torr to 0.1 Torr.

13. The method according to claim 10, wherein the dopant includes one or more boron (B), nitrogen (N), carbon (C), phosphorous (P), arsenic (As), aluminum (Al), or germanium (Ge).

14. The method according to claim 10, wherein the Si-containing layer is entirely removed and absorbed into the selector pattern during the ion implantation process.

15. The method according to claim 10, wherein, during the ion implantation process, a portion of the initial buffer layer is removed and absorbed into the selector pattern and another portion of the initial buffer layer remains as a buffer layer under the selector pattern or the Si-containing layer, or the initial buffer layer is entirely removed and absorbed into the selector pattern.

16. The method according to claim 15, wherein the buffer layer has a thickness in a range of greater than 0 Å and less than or equal to 10 Å.

17. A method for fabricating a semiconductor device including a plurality of memory cells, the method comprising:
forming an initial capping layer on the plurality of memory cell; and
performing a radical oxidation process so that a first portion of the initial capping layer is converted into a second capping layer including an oxide and a second portion of the initial capping layer remains as a first capping layer under the second capping layer.

18. The method according to claim 17, wherein the initial capping layer includes Si₃N₄, SiOₓN_{y}, WSiₓ, CoSiₓ, SiOC, SiC, SiCN, amorphous Si, or poly-Si, or a combination thereof.

19. The method according to claim 17, wherein the first capping layer has a thickness in a range of less than or equal to 20% of a thickness of the second capping layer.

20. The method according to claim 17, wherein the radical oxidation process is performed by a low-temperature plasma process under a pressure of 10 mTorr to 10 Torr, a temperature of 100° C. to 500° C., and radio frequency power of 100 W to 5 kW, or by using H₂ and O₂ gases under a temperature of 700° C. or higher and a pressure of 10 Torr to 0.1 Torr.

21. The method according to claim 17, wherein a thickness of the initial capping layer is determined in consideration of a thickness of the first capping layer and a thickness of the second capping layer.

22. The method according to claim 17, wherein a thickness of the second capping layer is greater than a value obtained by subtracting a thickness of the first capping layer from a thickness of the initial capping layer.
